(19) United States
(12) Patent Application Publication
(10) Pub. No.: US 2025/0379595 A1
(43) Pub. Date: Dec. 11, 2025

(54) Low-Latency Decompressor

(71) Applicant: MARVELL ASIA PTE LTD, Singapore (SG)

(72) Inventors: Steven Craig BARNER, Shrewsbury, MA (US); David FENTON, Kanata (CA); Nicholas MARIAM, Somerville, MA (US); Dennis ELLERT, Bragg Creek (CA); Ilian TZVETANOV, Ottowa (CA)

(21) Appl. No.: 19/230,455

(22) Filed: Jun. 6, 2025

Related U.S. Application Data
(60) Provisional application No. 63/657,103, filed on Jun. 6, 2024.

(51) Int. Cl. H03M 7/30

(52) U.S. Cl. CPC H03M 7/3088; H03M 7/6005; H03M 7/6058

(57) ABSTRACT

An example method of low-latency decompression includes receiving a data read request to read data stored, in a compressed storage format, in a memory, and responsive to receiving the data read request, accessing compressed data sequences, splitting the compressed data sequences into three separate streams for parallel processing, the three separate streams including (i) a literal stream, (ii) a history cache stream, and (iii) a history buffer stream, for each data sequence in the literal stream, determining a literal decompressed block offset for the data sequence, for each data sequence in the history cache stream, determining a decompressed block offset using one or more history cache pointers associated with the data sequence, for each data sequence in the history buffer stream, determining the decompressed block offset via a history buffer, and generating a data output responsive to the data read request.

### CROSS-REFERENCE TO RELATED APPLICATION

This application claims the benefit of U.S. Provisional Application No. 63/657,103, filed on Jun. 6, 2024. The entire disclosure of the application referenced above is incorporated herein by reference.

### FIELD

The present disclosure relates to a low-latency decompressor.

### BACKGROUND

The background description provided herein is for the purpose of generally presenting the context of the disclosure. Work of the presently named inventors, to the extent the work is described in this background section, as well as aspects of the description that may not otherwise qualify as prior art at the time of filing, are neither expressly nor impliedly admitted as prior art against the present disclosure.

Data may be stored in memory in a compressed format to save storage space, such as an LZ4 compression format where repeating patterns in the data are encoded as matches. The matches are encoded with an associated match length and relative offset to previous data, in a series of compressed data sequences.

### SUMMARY

An example method of low-latency decompression includes receiving a data read request to read data stored, in a compressed storage format, in a memory, and responsive to receiving the data read request, accessing compressed data sequences corresponding to the data stored in the compressed storage format, splitting the compressed data sequences into three separate streams for parallel processing, the three separate streams including (i) a literal stream, (ii) a history cache stream, and (iii) a history buffer stream, for each data sequence in the literal stream, determining a literal decompressed block offset for the data sequence and writing decompressed output data from the data sequence into an assembly buffer, for each data sequence in the history cache stream, determining a decompressed block offset using one or more history cache pointers associated with the data sequence, and writing decompressed output data from the data sequence into the assembly buffer, for each data sequence in the history buffer stream, determining the decompressed block offset via a history buffer, and writing decompressed output data from the data sequence into the assembly buffer, and generating a data output responsive to the data read request, at least partially based on data stored in the assembly buffer.

In some examples, the literal stream includes data sequences including raw bytes of data without back reference pointers, the history cache stream includes data sequences including back reference pointers which are less than a specified threshold number of bytes prior to a first byte of the data sequence, and the history buffer stream includes data sequences including back reference pointers which are greater than the specified threshold number of bytes prior to the first byte of the data sequence.

In some examples, for each data sequence in the literal stream, determining a literal decompressed block offset for the data sequence includes processing a raw byte of data in one path through the assembly buffer to the data output.

In some examples, the method includes updating a history buffer including decompressed block offsets, wherein determining the decompressed block offset via the history buffer includes reading one or more decompressed block offsets from the history buffer.

In some examples, the method includes maintaining a history cache of bytes associated with data sequences from the history cache stream, wherein generating the data output includes merging data from the history cache with processed data sequences from the literal stream and the history buffer stream.

In some examples, the method includes, for each individual data sequence in the history cache stream identifying one or more relative history pointers associated with the individual data sequence, and resolving each of the one or more relative history pointers to an absolute pointer, the absolute pointer referring to a data byte before a first byte of the individual data sequence.

In some examples, resolving each of the one or more relative history pointers includes resolving different ones of the one or more relative history pointers at different clock cycles of processing the history cache stream.

In some examples, resolving each of the one or more relative history pointers includes resolving all of the one or more relative history pointers associated with the individual data sequence in less than or equal to eight clock cycles.

In some examples, the method includes assigning a data sequence to the history cache stream in response to a back reference pointer of the data sequence being less than a specified threshold number of bytes prior to a first byte of the data sequence, and assigning the data sequence to the history buffer stream in response to the back reference pointer of the data sequence being greater than the specified threshold number of bytes prior to the first byte of the data sequence.

In some examples, the specified threshold number of bytes is 128 bytes prior to the first byte of the data sequence. In some examples, each of the literal stream, the history cache stream and the history buffer stream are assigned a guaranteed write bandwidth into the assembly buffer. In some examples, the assembly buffer includes at least sixteen memories, and each of the at least sixteen memories includes at least seven write ports.

In some examples, the method includes maintaining a history cache of bytes associated with data sequences from the history cache stream, wherein the history cache includes a multiplexer for selecting any byte in the history cache.

In some examples, for each of the at least sixteen memories at least one of the at least seven write ports is configured to write data from the literal stream, at least two of the at least seven write ports are configured to write data from the history cache stream, and at least four of the at least seven write ports are configured to write data from the history buffer stream.

In some examples, the compressed data sequences are stored in memory in an LZ4 compression format. In some examples, the assembly buffer includes at least one of multi-ported flop data structures or latch array data structures. In some examples, generating the data output includes generating the data output at an output rate of at least thirty Gigabytes per second.

An example low-latency decompressor includes a memory configured to store data in a compressed storage format, an assembly buffer configured to store decompressed block offsets associated with data sequences, a history buffer configured to store bytes associated with data sequences for reading during processing of a history buffer stream, a history cache configured to store bytes associated with data sequences from a history cache stream, and at least one processor configured to receive a data read request to read data stored in the memory, and responsive to the data read request, access compressed data sequences stored in the memory and corresponding to the data read request, split the compressed data sequences into three separate streams for parallel processing, the three separate streams including a literal stream, the history cache stream and the history buffer stream, for each data sequence in the literal stream, determine a literal decompressed block offset for the data sequence and write decompressed output data from the data sequence into an assembly buffer, for each data sequence in the history cache stream, determine a decompressed block offset using one or more history cache pointers associated with the data sequence, and write decompressed output data from the data sequence into the assembly buffer, for each data sequence in the history buffer stream, determine the decompressed block offset via a history buffer, and write decompressed output data from the data sequence into the assembly buffer, and generate a data output responsive to the data read request, at least partially based on data stored in the assembly buffer.

In some examples, the literal stream includes data sequences including raw bytes of data without back reference pointers, the history cache stream includes data sequences including back reference pointers which are less than a specified threshold number of bytes prior to a first byte of the data sequence, and the history buffer stream includes data sequences including back reference pointers which are greater than the specified threshold number of bytes prior to the first byte of the data sequence.

In some examples, for each data sequence in the literal stream, determining a literal decompressed block offset for the data sequence includes processing a raw byte of data in one path through the assembly buffer to the data output.

In some examples, the at least one processor is configured to update a history buffer including decompressed block offsets, wherein determining the decompressed block offset via the history buffer includes reading one or more decompressed block offsets from the history buffer, and maintain a history cache of bytes associated with data sequences from the history cache stream, wherein generating the data output includes merging data from the history cache with processed data sequences from the literal stream and the history buffer stream.

In some examples, the at least one processor is configured to, for each individual data sequence in the history cache stream identify one or more relative history pointers associated with the individual data sequence, and resolve each of the one or more relative history pointers to an absolute pointer, the absolute pointer referring to a data byte before a first byte of the individual data sequence.

In some examples, the at least one processor is configured to assign a data sequence to the history cache stream in response to a back reference pointer of the data sequence being less than a specified threshold number of bytes prior to a first byte of the data sequence, and
assign the data sequence to the history buffer stream in response to the back reference pointer of the data sequence being greater than the specified threshold number of bytes prior to the first byte of the data sequence.

In some examples, the assembly buffer includes at least sixteen memories, each of the at least sixteen memories includes at least seven write ports, the history cache includes a multiplexer for selecting any byte in the history cache, and the assembly buffer includes at least one of multi-ported flop data structures or latch array data structures.

In some examples, the compressed data sequences are stored in memory in an LZ4 compression format, and generating the data output includes generating the data output at an output rate of at least thirty Gigabytes per second.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF DRAWINGS

FIG. 1 is a block diagram of an example low-latency decompressor.

FIG. 2 is a flowchart illustrating an example process for decompressing stored data, responsive to a read data request.

FIG. 3 is a block diagram of an example sequence of compressed data including literal blocks and match offset blocks.

FIG. 4 is a block diagram of an example sequence of compressed data including pointers to other blocks within the compressed data sequence.

FIG. 5 is a block diagram of an example sequence of compressed data bytes already in a history and bytes not directly referenced from the history.

FIG. 6 is a flowchart illustrating an example process for decompressing data via parallel streams including a literal stream, a history cache stream and a history buffer stream.

FIG. 7 is a flowchart illustrating an example process for resolving relative history pointers for decompressing stored data.

In the drawings, reference numbers may be reused to identify similar and/or identical elements.

### DESCRIPTION

Data may be stored in memory a compressed format to save storage space, such as an LZ4 compression format where repeating patterns in the data are encoded as matches. The matches are encoded with an associated match length and relative offset to previous data, in a series of compressed data sequences. Some software decompressors are configured to walk through the encoded format and reconstruct the original file one byte at a time. Some hardware decompressors may be configured to process more than one byte at a time, but may not be able to handle more than one match at time within the compressed data sequences.

In some examples, a low-latency decompressor is configured to achieve a high degree of parallelism when decompressing an input data stream stored in a compressed data format (such as an LZ4 compression format). For example, a compressed data sequence may be split into three separate streams for processing, such as by processing a literal stream of compressed data sequences which do not include any lookup pointers, a history buffer stream of compressed data sequences which include lookup pointers that may be read from a history buffer of bytes (e.g., when back reference pointers are greater than a threshold number of bytes prior to a first byte of the data sequence), and a history cache stream of compressed data sequences which include lookup pointers which are processed using a history cache (e.g., when back reference pointers are less than the threshold number of bytes prior to the first byte of the data sequence).

Different data structures within the low-latency decompressor may have many access ports, to facilitate a high level of parallelism when processing different streams of the compressed data sequences. The history cache may be configured to resolve history cache pointers, including pointers to earlier bytes in a same output word, with a reduced or minimal delay. For example, a low-latency decompressor may achieve high average output rates and peak output rates, such as at least 19.2 Gigabytes per second once an input pipeline is filled, at least 36.9 Gigabytes per second after the input pipeline is filled, at least 30.3 Gigabytes per second if input pipeline delays are included in the processing time (e.g., for four kilobyte output files), a peak output rate of at least 38.4 Gigabytes per second, etc. Other example embodiments may include other output rates.

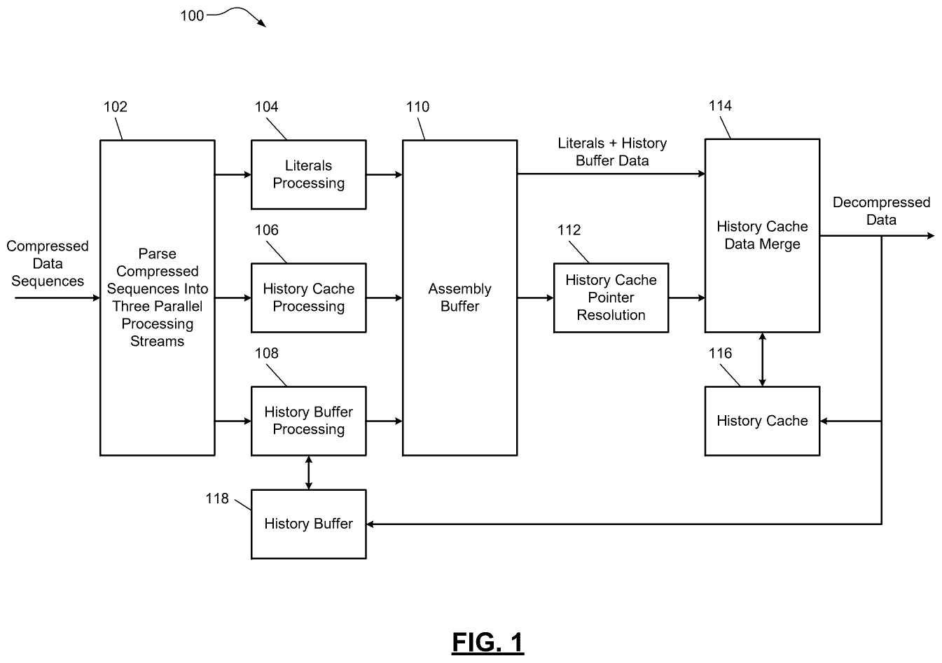

FIG. 1 is a block diagram of an example low-latency decompressor 100. The low-latency decompressor 100 includes a parsing module 102 configured to parse compressed data sequences at an input of the parsing module 102. For example, the parsing module 102 may be configured to read compressed input data stored in memory in an LZ4 compression format, and parse the compressed data sequences into three parallel processing streams.

A literals processing stream 104 may be configured to process literal data sequences which do not include any reference pointers to other blocks of data in the same or other data sequences. For example, the literals processing stream 104 may be configured to process raw bytes of data and store decompressed blocks in the assembly buffer 110.

A history cache processing stream 106 may be configured to process data sequences including reference pointers which are less than the threshold number of bytes prior to the first byte of the data sequence. For example, if an input data sequence includes a pointer which is less than 128 bytes prior to a first byte of the input data sequence (or a threshold of more or less bytes in other examples), the input data sequence may be processed using a history cache 116 because data blocks referenced by the pointer are not yet available in the history buffer 118.

A history buffer processing stream 108 may be configured to process data sequences including reference pointers which are greater than the threshold number of bytes prior to the first byte of the data sequence. For example, if an input data sequence includes a pointer which is more than 128 bytes prior to a first byte of the input data sequence (or a threshold of more or less bytes in other examples), the input data sequence may be processed by reading data from blocks referenced by the pointer which have already been stored in the history buffer 118.

The assembly buffer 110 may be configured to receive decompressed data blocks from the literals processing stream 104, the history cache processing stream 106, and the history buffer processing stream 108. For example, each of the literals processing stream 104, the history cache processing stream 106, and the history buffer processing stream 108 may be configured to move data sequences forward independently of one another. Each of the literals processing stream 104, the history cache processing stream 106, and the history buffer processing stream 108 may determine correct decompressed block offsets for its output data, and then write that output data into the assembly buffer 110.

Data structures within the low-latency decompressor may use multi-ported flop arrays, latch arrays, etc., to provide a higher throughput, increased parallelism and lower latency (e.g., as compared to random access memory at high clock frequency). The assembly buffer 110 may be write-intensive, while history structures such as the history cache 116 and the history buffer 118 are read-intensive.

In some examples, the assembly buffer 110 may include sixteen memory banks, each having seven write ports (e.g., at one byte wide), to define a massively parallel write structure. Each memory bank may include one read port in addition to the seven write ports. The history buffer 118 may include two memory banks, each having two read ports which are sixteen bytes wide, and one write port.

The history cache 116 may include one write port which is sixteen bytes wide, and sixteen read ports which are each one byte wide, to define a massively parallel read structure. For example, the history cache 116 may operate similar to a 144:1 multiplexer, to allow for selection of any byte in the history cache 116. Other examples may include more or less memory banks, more or less read and write ports, more or less bytes per read or write, etc., for each of the assembly buffer 110, the history buffer 118 and the history cache 116.

Different write ports of the assembly buffer 110 may be assigned to receive data from different ones of the literals processing stream 104, the history cache processing stream 106, and the history buffer processing stream 108. In the example of the assembly buffer 110 having sixteen separate one byte wide flop arrays, each with seven write ports, one write port may be assisted to the literals processing stream 104, two write ports may be assigned to the history cache processing stream 106, and four write ports may be assigned to the history buffer processing stream 108.

The literals processing stream 104 and the history cache processing stream 106 may be split into sixteen independent one byte lanes, each having dedicated write bandwidth into its corresponding assembly buffer lane. This may facilitate per-byte-lane addressing to simplify data rotation. Each history buffer read response lane may be assigned its own port. For example, allowing each read lane to write up to sixteen bytes of match data to the assembly buffer 110, with arbitrary data rotation, may allow long matches to execute very quickly. This may be useful if the sequences after the long match are short matches that need more processing time.

While the literals processing stream 104 and the history cache processing stream 106 may be easily pipelined, processing within the assembly buffer 110, the history cache pointer resolution module 112 and the history cache data merge 114 may be completed within a time that is determined by a capacity of the history cache 116. For example, the more pipeline stages that are added beyond the literals processing stream 104 and the history cache processing stream 106, the deeper the history cache 116 needs to be to cover extra latency. It may be important to resolve final pointers quickly in the history cache pointer resolution module 112, because the history cache 116 cannot be deepened arbitrarily without reducing the clock frequency.

Regarding the history cache processing stream 106, within each individual sequence, each relative history pointer may be resolved to an absolute pointer which refers to a data byte before the first byte of the sequence. In the history cache pointer resolution module 112, the worst-case pointer resolution at the most time-sensitive part of the design may be simplified. Instead of resolving the pointers byte by byte, the only remaining uncertainty may be across sequences. Each sequence may be at least four bytes long in some examples, so an entire sixteen byte output may be resolved in a small number of iterations.

For example, the history cache pointer resolution module 112 may be configured to resolve relative pointers using one or more layers of iterative math, to resolve any remaining pointers across multiple data sequences (e.g., multiple data sequences of an LZ4 compression format which include relative pointers). Because LZ4 sequences can be as small as 4 B, for a 16 B output bus for example, the history cache pointer resolution module 112 may be configured to resolve up to four cross-sequence references in each beat of output data.

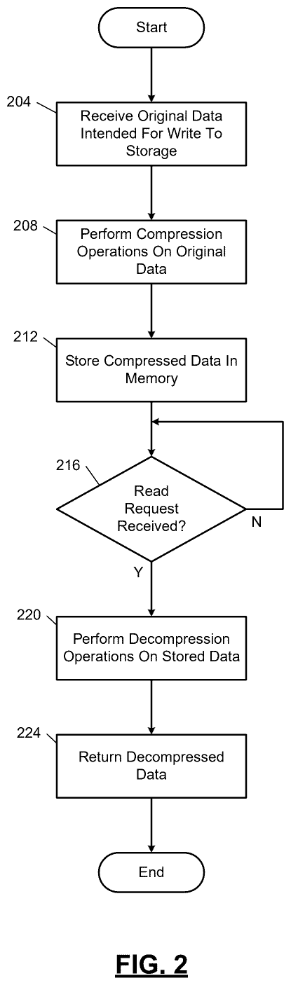

FIG. 2 is a flowchart illustrating an example process for decompressing stored data, responsive to a read data request. At 204, the process begins by receiving original data intended for writing to storage in memory. At 208, the process performs compressions operations on the original data. For example, the original data may be compressed into an LZ4 compression format.

At 212, the process stores the compressed data in memory. The process then waits at 216 to receive a data read request associated with the stored compressed data. Once a data read request is received at 216, the process performs decompression operations on the stored data at 220. The decompressed data is then returned at 224, responsive to the received read request.

Although some compression/decompression algorithms are focused on storage optimization and are implemented in software (e.g., GZIP, ZLIB, etc.), there is increased interest in high-speed, low-latency compression/decompression for storage, memory expansion and networking. For example, decompression rates may be greater than 200 Gbps per engine. Simpler algorithms may be sufficient in these cases, such as an LZ4 data compression format for storing compressed data. As an example, Iliad is a CXL memory expander product, where compressed data is stored in DRAM, and expanded data is stored in a last-level cache.

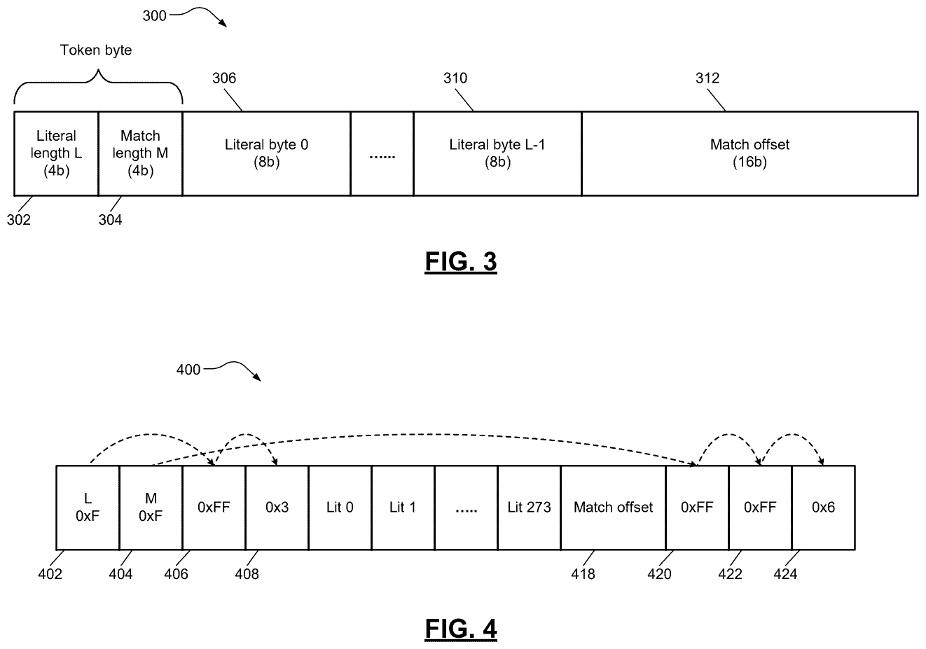

FIG. 3 is a block diagram of an example sequence 300 of compressed data including literal blocks and match offset blocks. The LZ4 data compression format is a simple byte-oriented dictionary algorithm, which is part of the LZ77 family. The LZ4 data compression format aims to provide a good trade-off between speed and compression ratio. For example, the LZ4 compression format does not require Huffman or arithmetic encoding after a history search.

A compressed block consists of a series of LZ4 sequences, each describing a set of “literals” (which may have a minimum length of zero bytes), and a match (which may have a minimum length of four bytes. FIG. 3 illustrates a literal block 302 having a length of four bits, and a match block 304 having a length of four bits. The literal block 302 and the match block 304 may define a token byte. The example sequence 300 of FIG. 3 includes a literal byte 306 having a length of eight bits, another literal byte 310 having a length of eight bits, and a match offset 312 having a length of sixteen bits.

FIG. 4 is a block diagram of an example sequence 400 of compressed data including pointers to other blocks within the compressed data sequence. In some examples, the LZ4 algorithm may not be able to output decompression data until it finds a first match. The algorithm may produce may short four byte matches, which are difficult to process at speed. The algorithm may require the compressed data stream to be parsed iteratively, byte by byte. For literal lengths above 14, or match lengths above 18, bytes beyond the token may be used to extend the length by up to 255. This may be a simple scheme for software loops, but can create undesirable ripples for hardware processing.

In the example sequence 400, a number of literals is 0xF+0xFF+0x3=273 bytes. For example, a first literal block 402, a second literal block 406 and a third literal block may be added together to specify a number of bytes. A match block 404 is located between the first literal block 402 and the second literal block 406.

The example sequence 400 includes a match offset 418. The match length is 0x4+0xF+0xFF+0xFF+0x6=535 bytes. For example, a first match offset block 420, a second match offset block 422 and a third match offset block 424 may be located after the match offset 418.

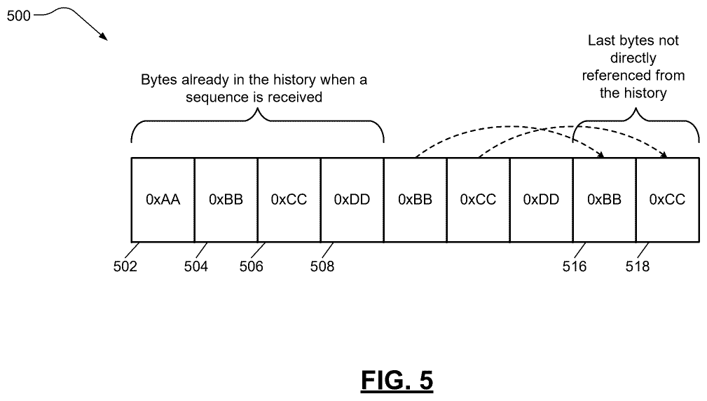

FIG. 5 is a block diagram of an example sequence 500 of compressed data bytes already in a history, and bytes not directly referenced from the history. History-based algorithms allow the length of a match to be greater than the match offset. Some of the data may not be directly available in the history at the time the sequence is received, which can create another ripple problem to address.

In the example sequence 500, the bytes 502, 504, 506 and 508 are already in a history when a sequence is received. A history write pointer match may be processed as go back three, length five. In the example sequence 500, the last bytes 516 and 518 may not be directly referenced from the history. Design challenges in the example sequences of FIGS. 3, 4 and 5 may be addressed by example hardware processing architectures described herein, such as the low-latency decompressor 100 of FIG. 1.

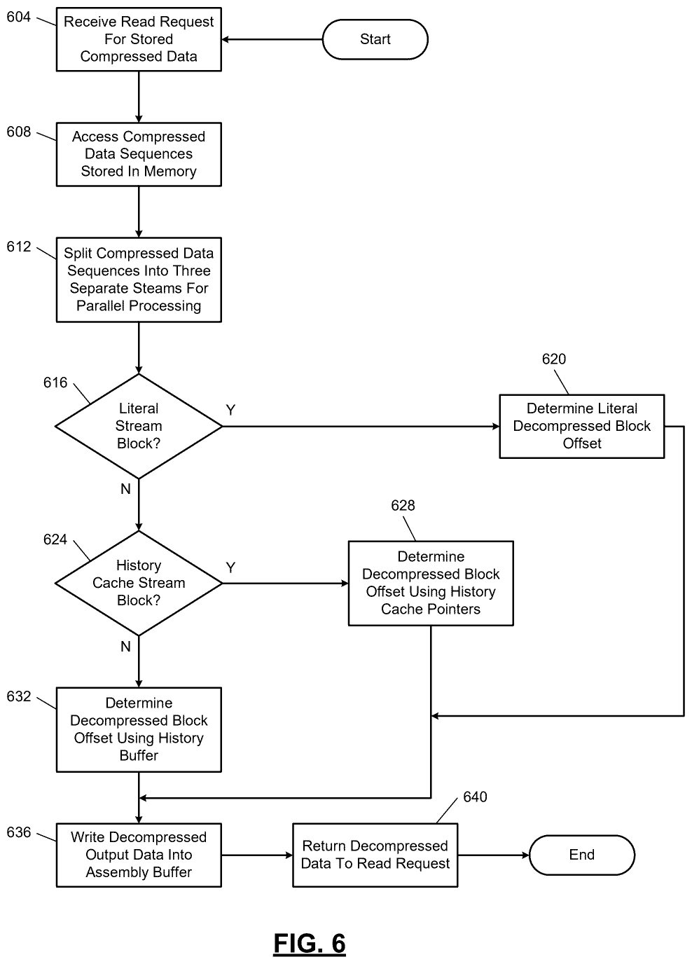

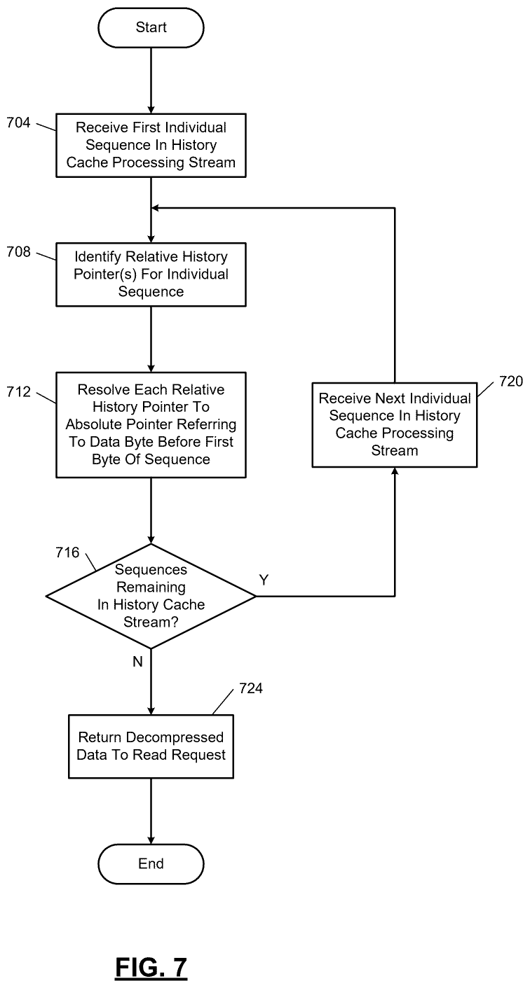

FIG. 6 is a flowchart illustrating an example process for decompressing data via parallel streams including a literal stream, a history cache stream and a history buffer stream. At 604, the process begins by receiving a read request for stored compressed data. The process accesses compressed data sequences in memory at 608, which correspond to the received data read request.

At 612, the process splits the compressed sequences into three separate streams for parallel processing. For example, the compressed data sequences may be separated (e.g., parsed) into a literals processing stream, a history cache processing stream, and a history buffer processing stream, as described above.

At 616, the process determines whether a literal stream block is being processed. If so, the process proceeds to 620 to determine a literal decompressed block offset for the literal block. If the data sequence is not a literal stream block at 616, the process determines at 624 whether the data sequence of the input is a history cache stream sequence.

If the data sequence of the input is a history cache stream sequence at 624, the process proceeds to 628 to determine a decompressed block offset using history cache pointers. If the input data sequence does not belong to the history cache processing stream at 624, the process determines the decompressed block offset using a history buffer at 632. The steps 616, 624 and 632 may operate in a parallel manner, independent of one another, based on parsing input data sequences of compressed data into a corresponding literals processing stream, history cache processing stream, or history buffer processing stream.

At 636, the process writes the decompressed output data into the assembly buffer, such as the assembly buffer 110. Writing the decompressed output data into the assembly buffer may include writing data to dedicated write ports of the assembly buffer assigned to respective data processing streams. At 640, the process returns decompressed data responsive to the data read request.

FIG. 7 is a flowchart illustrating an example process for resolving relative history pointers for decompressing stored data. At 704, the process receives a first individual sequence in the history cache processing stream. At 708, the process identifies relative history pointers for individual sequences.

At 712, the process resolves each relative history pointer to an absolute history pointer, which refers to a data byte before the first byte of the individual data sequence. For example, a history cache pointer resolution module may be configured to resolve relative pointers using one or more layers of iterative math at 712, to resolve any remaining pointers across multiple data sequences (e.g., multiple data sequences of an LZ4 compression format which include relative pointers). Because LZ4 sequences can be as small as 4 B, for a 16 B output bus for example, the history cache pointer resolution module may be configured to resolve up to four cross-sequence references in each beat of output data.

At 716, the process determines whether any sequences remain in the history cache data processing stream. If input sequences of compressed data remain at 716 which have not been processed, control proceeds to 720 to receive a next individual sequence in the history cache processing stream, and the process returns to 708 to identify a relative history pointer for the next received individual sequence. Once all data sequences in the history cache processing stream have been processed at 716, the process proceeds to 724 to return the decompressed data responsive to the data read request.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In the figures, the direction of an arrow, as indicated by the arrowhead, generally demonstrates the flow of information (such as data or instructions) that is of interest to the illustration. For example, when element A and element B exchange a variety of information but information transmitted from element A to element B is relevant to the illustration, the arrow may point from element A to element B. This unidirectional arrow does not imply that no other information is transmitted from element B to element A. Further, for information sent from element A to element B, element B may send requests for, or receipt acknowledgements of, the information to element A.

In this application, including the definitions below, the term “module” or the term “controller” may be replaced with the term “circuit.” The term “module” may refer to, be part of, or include: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor circuit (shared, dedicated, or group) that executes code; a memory circuit (shared, dedicated, or group) that stores code executed by the processor circuit; other suitable hardware components that provide the described functionality; or a combination of some or all of the above, such as in a system-on-chip.

The module may include one or more interface circuits. In some examples, the interface circuits may include wired or wireless interfaces that are connected to a local area network (LAN), the Internet, a wide area network (WAN), or combinations thereof. The functionality of any given module of the present disclosure may be distributed among multiple modules that are connected via interface circuits. For example, multiple modules may allow load balancing. In a further example, a server (also known as remote, or cloud) module may accomplish some functionality on behalf of a client module.

The term code, as used above, may include software, firmware, and/or microcode, and may refer to programs, routines, functions, classes, data structures, and/or objects. The term shared processor circuit encompasses a single processor circuit that executes some or all code from multiple modules. The term group processor circuit encompasses a processor circuit that, in combination with additional processor circuits, executes some or all code from one or more modules. References to multiple processor circuits encompass multiple processor circuits on discrete dies, multiple processor circuits on a single die, multiple cores of a single processor circuit, multiple threads of a single processor circuit, or a combination of the above. The term shared memory circuit encompasses a single memory circuit that stores some or all code from multiple modules. The term group memory circuit encompasses a memory circuit that, in combination with additional memories, stores some or all code from one or more modules.

The term memory circuit is a subset of the term computer-readable medium. The term computer-readable medium, as used herein, does not encompass transitory electrical or electromagnetic signals propagating through a medium (such as on a carrier wave); the term computer-readable medium may therefore be considered tangible and non-transitory. Non-limiting examples of a non-transitory, tangible computer-readable medium are nonvolatile memory circuits (such as a flash memory circuit, an erasable programmable read-only memory circuit, or a mask read-only memory circuit), volatile memory circuits (such as a static random access memory circuit or a dynamic random access memory circuit), magnetic storage media (such as an analog or digital magnetic tape or a hard disk drive), and optical storage media (such as a CD, a DVD, or a Blu-ray Disc).

In this application, apparatus elements described as having particular attributes or performing particular operations are specifically configured to have those particular attributes and perform those particular operations. Specifically, a description of an element to perform an action means that the element is configured to perform the action. The configuration of an element may include programming of the element, such as by encoding instructions on a non-transitory, tangible computer-readable medium associated with the element.

The apparatuses and methods described in this application may be partially or fully implemented by a special purpose computer created by configuring a general purpose computer to execute one or more particular functions embodied in computer programs. The functional blocks, flowchart components, and other elements described above serve as software specifications, which can be translated into the computer programs by the routine work of a skilled technician or programmer.

The computer programs include processor-executable instructions that are stored on at least one non-transitory, tangible computer-readable medium. The computer programs may also include or rely on stored data. The computer programs may encompass a basic input/output system (BIOS) that interacts with hardware of the special purpose computer, device drivers that interact with particular devices of the special purpose computer, one or more operating systems, user applications, background services, background applications, etc.

The computer programs may include: (i) descriptive text to be parsed, such as HTML (hypertext markup language), XML (extensible markup language), or JSON (JavaScript Object Notation) (ii) assembly code, (iii) object code generated from source code by a compiler, (iv) source code for execution by an interpreter, (v) source code for compilation and execution by a just-in-time compiler, etc. As examples only, source code may be written using syntax from languages including C, C++, C #, Objective-C, Swift, Haskell, Go, SQL, R, Lisp, Java®, Fortran, Perl, Pascal, Curl, OCaml, Javascript®, HTML5 (Hypertext Markup Language 5th revision), Ada, ASP (Active Server Pages), PHP (PHP: Hypertext Preprocessor), Scala, Eiffel, Smalltalk, Erlang, Ruby, Flash®, Visual Basic®, Lua, MATLAB, SIMULINK, and Python®.

What is claimed is:

1. A method of low-latency decompression, the method comprising:
receiving a data read request to read data stored, in a compressed storage format, in a memory; and
responsive to receiving the data read request,
accessing compressed data sequences corresponding to the data stored in the compressed storage format,
splitting the compressed data sequences into three separate streams for parallel processing, the three separate streams including (i) a literal stream, (ii) a history cache stream, and (iii) a history buffer stream,
for each data sequence in the literal stream, determining a literal decompressed block offset for the data sequence and writing decompressed output data from the data sequence into an assembly buffer,
for each data sequence in the history cache stream, determining a decompressed block offset using one or more history cache pointers associated with the data sequence, and writing decompressed output data from the data sequence into the assembly buffer,
for each data sequence in the history buffer stream, determining the decompressed block offset via a history buffer, and writing decompressed output data from the data sequence into the assembly buffer, and
generating a data output responsive to the data read request, at least partially based on data stored in the assembly buffer.

2. The method of claim 1, wherein:
the literal stream includes data sequences including raw bytes of data without back reference pointers;
the history cache stream includes data sequences including back reference pointers which are less than a specified threshold number of bytes prior to a first byte of the data sequence; and
the history buffer stream includes data sequences including back reference pointers which are greater than the specified threshold number of bytes prior to the first byte of the data sequence.

3. The method of claim 1, wherein for each data sequence in the literal stream, determining a literal decompressed block offset for the data sequence includes processing a raw byte of data in one path through the assembly buffer to the data output.

4. The method of claim 3, further comprising updating a history buffer including decompressed block offsets, wherein determining the decompressed block offset via the history buffer includes reading one or more decompressed block offsets from the history buffer.

5. The method of claim 4, further comprising maintaining a history cache of bytes associated with data sequences from the history cache stream, wherein generating the data output includes merging data from the history cache with processed data sequences from the literal stream and the history buffer stream.

6. The method of claim 1, further comprising, for each individual data sequence in the history cache stream:
identifying one or more relative history pointers associated with the individual data sequence; and
resolving each of the one or more relative history pointers to an absolute pointer, the absolute pointer referring to a data byte before a first byte of the individual data sequence.

7. The method of claim 6, wherein resolving each of the one or more relative history pointers includes resolving different ones of the one or more relative history pointers at different clock cycles of processing the history cache stream.

8. The method of claim 7, wherein resolving each of the one or more relative history pointers includes resolving all of the one or more relative history pointers associated with the individual data sequence in less than or equal to eight clock cycles.

9. The method of claim 1, further comprising:
assigning a data sequence to the history cache stream in response to a back reference pointer of the data sequence being less than a specified threshold number of bytes prior to a first byte of the data sequence; and
assigning the data sequence to the history buffer stream in response to the back reference pointer of the data sequence being greater than the specified threshold number of bytes prior to the first byte of the data sequence.

10. The method of claim 9, wherein the specified threshold number of bytes is 128 bytes prior to the first byte of the data sequence.

11. The method of claim 1, wherein each of the literal stream, the history cache stream and the history buffer stream are assigned a guaranteed write bandwidth into the assembly buffer.

12. The method of claim 10, wherein:
the assembly buffer includes at least sixteen memories; and
each of the at least sixteen memories includes at least seven write ports.

13. The method of claim 12, further comprising maintaining a history cache of bytes associated with data sequences from the history cache stream, wherein the history cache includes a multiplexer for selecting any byte in the history cache.

14. The method of claim 12, wherein for each of the at least sixteen memories:
at least one of the at least seven write ports is configured to write data from the literal stream;
at least two of the at least seven write ports are configured to write data from the history cache stream; and
at least four of the at least seven write ports are configured to write data from the history buffer stream.

15. The method of claim 1, wherein the compressed data sequences are stored in memory in an LZ4 compression format.

16. The method of claim 1, wherein the assembly buffer includes at least one of multi-ported flop data structures or latch array data structures.

17. The method of claim 1, wherein generating the data output includes generating the data output at an output rate of at least thirty Gigabytes per second.

18. A low-latency decompressor comprising:
a memory configured to store data in a compressed storage format;
an assembly buffer configured to store decompressed block offsets associated with data sequences;
a history buffer configured to store bytes associated with data sequences for reading during processing of a history buffer stream;
a history cache configured to store bytes associated with data sequences from a history cache stream; and
at least one processor configured to receive a data read request to read data stored in the memory, and responsive to the data read request,
access compressed data sequences stored in the memory and corresponding to the data read request,
split the compressed data sequences into three separate streams for parallel processing, the three separate streams including a literal stream, the history cache stream and the history buffer stream,
for each data sequence in the literal stream, determine a literal decompressed block offset for the data sequence and write decompressed output data from the data sequence into an assembly buffer,
for each data sequence in the history cache stream, determine a decompressed block offset using one or more history cache pointers associated with the data sequence, and write decompressed output data from the data sequence into the assembly buffer,
for each data sequence in the history buffer stream, determine the decompressed block offset via a history buffer, and write decompressed output data from the data sequence into the assembly buffer, and
generate a data output responsive to the data read request, at least partially based on data stored in the assembly buffer.

19. The low-latency decompressor of claim 18, wherein:
the literal stream includes data sequences including raw bytes of data without back reference pointers;
the history cache stream includes data sequences including back reference pointers which are less than a specified threshold number of bytes prior to a first byte of the data sequence; and
the history buffer stream includes data sequences including back reference pointers which are greater than the specified threshold number of bytes prior to the first byte of the data sequence.

20. The low-latency decompressor of claim 18, wherein for each data sequence in the literal stream, determining a literal decompressed block offset for the data sequence includes processing a raw byte of data in one path through the assembly buffer to the data output.

21. The low-latency decompressor of claim 20, wherein the at least one processor is configured to:
update a history buffer including decompressed block offsets, wherein determining the decompressed block offset via the history buffer includes reading one or more decompressed block offsets from the history buffer; and
maintain a history cache of bytes associated with data sequences from the history cache stream, wherein generating the data output includes merging data from the history cache with processed data sequences from the literal stream and the history buffer stream.

22. The low-latency decompressor of claim 18, wherein the at least one processor is configured to, for each individual data sequence in the history cache stream:
identify one or more relative history pointers associated with the individual data sequence; and
resolve each of the one or more relative history pointers to an absolute pointer, the absolute pointer referring to a data byte before a first byte of the individual data sequence.

23. The low-latency decompressor of claim 18, wherein the at least one processor is configured to:
assign a data sequence to the history cache stream in response to a back reference pointer of the data sequence being less than a specified threshold number of bytes prior to a first byte of the data sequence; and
assign the data sequence to the history buffer stream in response to the back reference pointer of the data sequence being greater than the specified threshold number of bytes prior to the first byte of the data sequence.

24. The low-latency decompressor of claim 18, wherein:
the assembly buffer includes at least sixteen memories;
each of the at least sixteen memories includes at least seven write ports;
the history cache includes a multiplexer for selecting any byte in the history cache; and
the assembly buffer includes at least one of multi-ported flop data structures or latch array data structures.

25. The low-latency decompressor of claim 18, wherein:
the compressed data sequences are stored in memory in an LZ4 compression format; and
generating the data output includes generating the data output at an output rate of at least thirty Gigabytes per second.
